(19) United States
(12) Patent Application Publication
(10) Pub. No.: US 2023/0184938 A1
(43) Pub. Date: Jun. 15, 2023

(54) ASSEMBLY COMPRISING A DISPLAY SCREEN AND A PROXIMITY SENSOR

(71) Applicants: STMICROELECTRONICS (RESEARCH & DEVELOPMENT) LIMITED, Marlow (GB); STMICROELECTRONICS (GRENOBLE 2) SAS, Grenoble (FR); STMICROELECTRONICS (ALPS) SAS, Grenoble (FR)

(72) Inventors: Joseph HANNAN, Edinburgh (GB); Adam CALEY, Fife (GB); Megane Estelle GUILLON, Saint Martin le Vinoux (FR); Charlotte MILANETTO, Grenoble (FR); Christophe PREMONT, Noyarey (FR)

(73) Assignees: STMICROELECTRONICS (RESEARCH & DEVELOPMENT) LIMITED, Marlow (GB); STMICROELECTRONICS (GRENOBLE 2) SAS, Grenoble (FR); STMICROELECTRONICS (ALPS) SAS, Grenoble (FR)

(21) Appl. No.: 18/062,517

(22) Filed: Dec. 6, 2022

(30) Foreign Application Priority Data
Dec. 15, 2021 (EP) 21306783.8

(51) Int. Cl. G01S 17/08; G01S 7/481

(52) U.S. Cl. CPC G01S 17/08; G01S 7/4813

(57) ABSTRACT

The present disclosure relates to an assembly for an electronic device, the assembly comprising: a display screen comprising a plurality of pixels arranged in a matrix scheme comprising rows orientated in a first direction and columns orientated in a second direction; and a proximity sensor comprising at least one optical light emitter, each adapted to emit a light beam through one or more first pixels of the display screen, and an optical detector adapted to receive through one or more second pixels of the display screen the light beam emitted by the at least one optical light emitter and reflected on an object; wherein none of the one or more second pixels is in the same row as any of the one or more first pixels, and none of the one or more second pixels is in the same column as any of the one or more first pixels.

### BACKGROUND

### Technical Field

The present disclosure relates generally to electronic devices, more particularly, to electronic devices comprising a display screen and a proximity sensor.

### Background Art

Electronic devices, such as mobile phones, e.g., smartphones, tablet computers, smartwatches, touchpads, laptop computers, comprising a screen displaying information and/or images destined for a user, for example a user of the device, are known.

Electronics devices comprising an optical package such as a proximity sensor are also known. A proximity sensor generally comprises an optical light emitter and an optical detector, generally housed in an optical package. The general principle of a proximity sensor is that the light emitter emits a light beam which is reflected on a target object and picked up by the optical detector. The optical detector may also be provided with other circuitry provided as part of said detector or associated therewith, which analyzes the output from said detector for a proximity sensing calculation.

The optical light emitter may comprise a light emitting diode (LED), a vertical cavity surface emitting laser (VCSEL) or an edge emitting laser (EEL).

The proximity sensor may be a time-of-flight (TOF) sensor type. For instance, TOF sensors generally comprise a VCSEL for emitting light radiation, and an array of Single Photon Avalanche Detectors (SPADs) or photodiodes for detecting the reflected light beam from the target object.

For certain applications, a proximity sensor is mounted on the same side of an electronic device as a display screen. In some cases, the proximity sensor can be positioned within a bezel which corresponds to a non-display area in a border region reserved for such devices, or a notch in the display screen. However, in order to increase the area of the display screen, it has been proposed to dispense with such a bezel or such a notch, and instead to place the proximity sensor behind the display screen, such that the optical light emitter transmits light through the display screen, and the optical detector picks up the emitted light after being reflected by a target object through the display screen again.

The display screen may be an organic light-emitting diode (OLED) type screen.

### BRIEF SUMMARY

There is a need for an assembly for an electronic device, comprising at least a display screen and a proximity sensor under the display screen, capable of limiting, or even suppressing, the aforementioned crosstalk effect due to the diffraction effect.

There is also a need for a proximity sensor, capable of limiting, or even suppressing, the aforementioned crosstalk effect due to the diffraction effect.

It would also be desirable that the solution is easy to implement.

One embodiment addresses all or some of the drawbacks of known electronic devices.

In one embodiment, is provided an assembly for an electronic device, the assembly comprising:
a display screen comprising a plurality of pixels arranged in a matrix scheme comprising rows orientated in a first direction and columns orientated in a second direction; and
a proximity sensor comprising at least one optical light emitter, each adapted to emit a light beam through one or more first pixels of the display screen, and an optical detector adapted to receive through one or more second pixels of the display screen the light beam emitted by the at least one optical light emitter and reflected on an object;
   wherein none of the one or more second pixels is in the same row as any of the one or more first pixels, and none of the one or more second pixels is in the same column as any of the one or more first pixels.

According to an embodiment, each common axis passing through the center of one of the at least one optical light emitter and the center of the optical detector is offset with regard to each of the first and second directions by an acute angle of at least 10° and at most 80°.

According to an embodiment, a first acute angle of the common axis with regard to the first direction is comprised between 10° and 45°.

According to an embodiment, a second acute angle of the common axis with regard to the second direction is comprised between 10° and 45°.

According to an embodiment, the display screen is an OLED screen, each pixel of the OLED screen having for instance a pentile subpixel arrangement.

According to an embodiment, the at least one optical light emitter and the optical detector are housed within an optical package, and each common axis passing through the center of one of the at least one optical light emitter and the center of the optical detector is substantially aligned with an edge of the optical package.

According to an embodiment, the at least one optical light emitter and the optical detector are housed within an optical package, and each common axis passing through the center of one of the at least one optical light emitter and the center of the optical detector is offset with regard to each of the edges of the optical package by an acute angle of at least 10° and at most 80°.

In one embodiment, is provided a proximity sensor comprising at least one optical light emitter, each adapted to emit a light beam through a display screen, and an optical detector adapted to receive through the display screen the light beam emitted by the at least one optical light emitter and reflected on an object, wherein the at least one optical light emitter and the optical detector are housed within an optical package, and each common axis passing through the center of one of the at least one optical light emitter and the center of the optical detector is offset with regard to each of the edges of the optical package by an acute angle of at least 10° and at most 80°.

According to an embodiment, the acute angle of each common axis with regard to each edge of the optical package is comprised between 10° and 45°.

According to an embodiment, the optical package is substantially rectangular or square, and at least a common axis is substantially orientated substantially in a diagonal of the optical package.

According to an embodiment, the optical detector comprises an array of light sensitive pixels having rows and columns of light sensitive pixels, said optical detector being orientated in order to align said rows of light sensitive pixels or said columns of light sensitive pixels substantially in the direction of the common axis.

According to an embodiment, the proximity sensor comprises at least two optical light emitters.

In one embodiment, is provided an electronic device comprising the assembly according to an embodiment or the proximity sensor according to an embodiment.

In one embodiment, is provided a method for forming an assembly comprising a display screen having a plurality of pixels arranged in a matrix scheme comprising rows orientated in a first direction and columns orientated in a second direction, and a proximity sensor;
the method comprising: placing a proximity sensor having at least one optical light emitter and an optical detector under the display screen, such that each of the at least optical light emitter is adapted to emit a light beam through one or more first pixels of the display screen, the optical detector is adapted to receive through one or more second pixels of the display screen the light beam emitted by the at least one emitter and reflected on an object, none of the one or more second pixels being in the same row as any of the one or more first pixels, and none of the one or more second pixels being in the same column as any of the one or more first pixels.

According to an embodiment, the method comprises:
providing a proximity sensor having at least one optical light emitter and an optical detector both housed within an optical package, each common axis passing through the center of one of the at least one optical light emitter and the center of the optical detector being substantially aligned with an edge of the optical package;
positioning the proximity sensor under the display screen;
rotating the proximity sensor in order to offset the edge of the optical package with regard to each of the first and second directions by an acute angle of at least 10° and at most 80°; and
assembling the proximity sensor to the display screen.

According to an embodiment, the method comprises:
providing a proximity sensor having at least one optical light emitter and an optical detector both housed within an optical package, each common axis passing through the center of one of the at least one optical light emitter and the center of the optical detector being offset with regard to each of the edges of the optical package by an acute angle of at least 10° and at most 80°; and
assembling the proximity sensor under the display screen so that each of the edges of the optical package is substantially aligned with the first direction or the second direction.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1A schematically illustrates an assembly comprising an OLED screen and a proximity sensor placed under the OLED screen;

FIG. 1B shows a diffraction pattern observed when a light beam is emitted and received through an OLED screen;

FIG. 1C schematically illustrates a crosstalk path induced by a light beam emitted from a proximity sensor through an OLED screen in the assembly of FIG. 1A;

FIG. 2 schematically illustrates an embodiment of an assembly for an electronic device;

FIG. 3 schematically illustrates another embodiment of an assembly for an electronic device;

FIG. 4A schematically illustrates another embodiment of an assembly for an electronic device;

FIG. 4B schematically illustrates a variant of the embodiment of FIG. 4A;

FIG. 5 schematically illustrates a reflection pattern emitted from a proximity sensor through an OLED screen in an assembly according to an embodiment;

FIG. 6 represents measurements of the crosstalk effect for different angles between the common angle of an optical light emitter and an optical detector in an assembly of an electronic device and the major axis of the electronic device.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the other components of an assembly or an electronic device integrating a display screen and a proximity sensor have not been detailed, the described embodiments being compatible with the usual other components of assemblies or electronic devices comprising a display screen. Similarly, the proximity sensor, in particular the optical light emitter(s) and the optical detector, and other components of a proximity sensor, have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal”, “vertical”, etc., reference is made to the orientation shown in the figures.

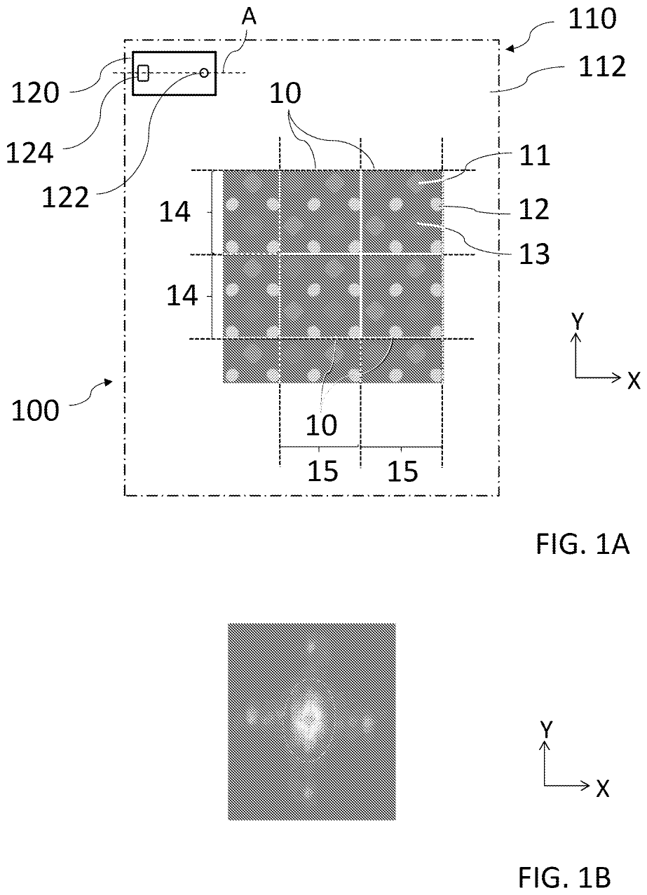

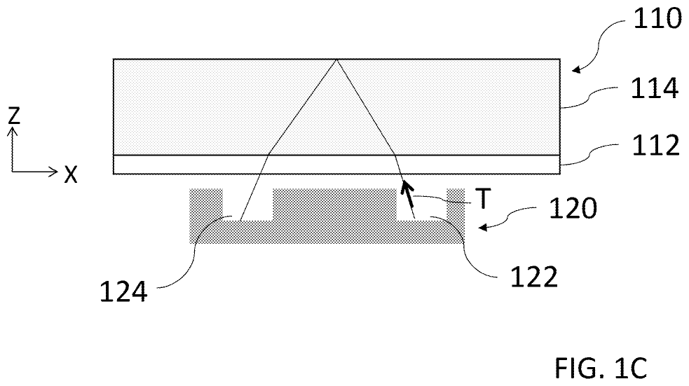

Referring to an electronic device such as a mobile phone, a tablet computer, a smartwatch, a touchpad, more generally to an electronic device having a substantially rectangular shape, the horizontal orientation (direction “X” in FIGS. 1A, 1B, 2, 3, 4A) corresponds for example to the minor axis of the electronic device, while the vertical orientation (direction “Y” in FIGS. 1A, 1B, 2, 3, 4A) corresponds for example to the major axis.

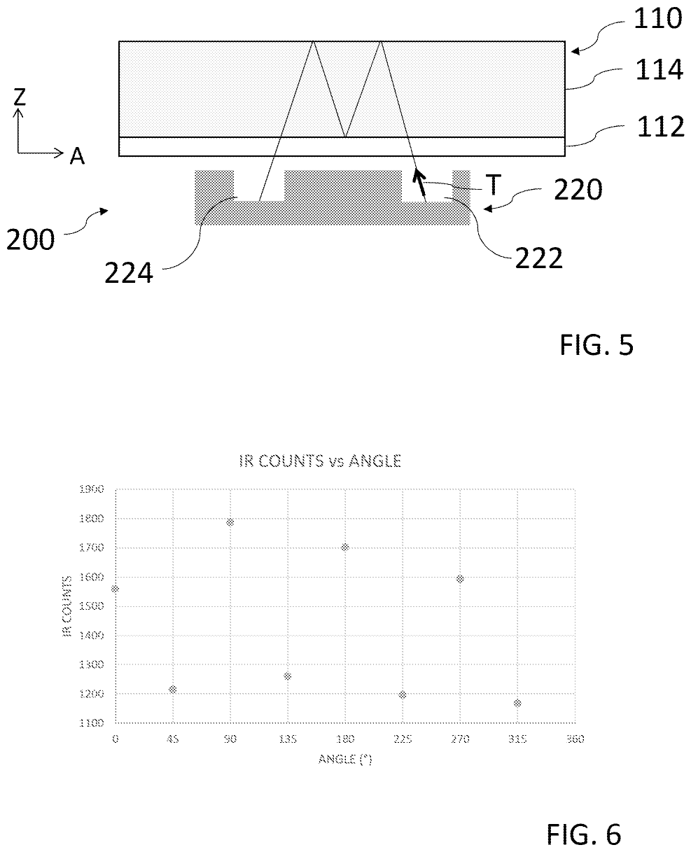

In addition, the terms “under” and “over” refer to the light propagation direction from the optical light emitter to the display screen (direction materialized by a thick horizontal arrow referenced “T” in FIGS. 1C and 5). The term “under” means before the display screen in the light propagation direction, and the term “over” means after the display screen in the light propagation direction.

Unless specified otherwise, the expressions “around,” “approximately,” “substantially” and “in the order of” signify within 10%, and in some embodiments within 5%.

An unwanted diffraction of a light passing through a display screen, for instance through an OLED screen, may occur when the light is emitted and received by the proximity sensor through a display screen. The diffraction effect increases the crosstalk effect between the emitter and the sensor, which may degrade the performances of the proximity sensor, due to unwanted (noise) optical reflection component caused by the reflection of the emitted optical light from a non-target object, such as a cover glass or an internal structure of the OLED screen, in addition to the useful optical reflection component caused by the reflection of the emitted optical signal at the target object. Techniques of the present disclosure resolve, among others, this technical problem.

FIG. 1A schematically illustrates an assembly 100 comprising an OLED display screen 110 having an OLED layer 112, and a proximity sensor 120 placed under the OLED layer 112. The OLED display screen 110 comprises generally a cover glass 114 on the OLED layer 112, as illustrated in FIG. 1C.

In this example, the OLED layer 112 has a diamond pentile subpixel arrangement, shown partially, and enlarged, in the OLED layer 112 of FIG. 1A for sake of clarity. As illustrated, a diamond pentile subpixel arrangement is a geometric arrangement of RGB (Red, Green, Blue) subpixels 11, 12, 13 in each pixel 10 of the OLED layer, in which the green pixels 12 interleave with alternating red 11 and blue 13 subpixels, with twice as many green subpixels as blue subpixels and red subpixels. The blue subpixels 13 are the largest subpixels, followed closely by the red subpixels 11, the greens subpixels 12 being much smaller than the red and the blue subpixels. Other shapes and/or arrangements of subpixels may be provided in the OLED layer, such as circular shapes and/or other pentile subpixel arrangements, or even common or alternated stripes arrangements.

The pixels 10 of the OLED layer are arranged in rows 14 and columns 15, this arrangement being key to the diffraction orientation, as explained hereafter. The rows are orientated in the horizontal direction X and the columns are orientated in the vertical direction Y.

The proximity sensor 120 comprises an optical light emitter 122 and an optical detector 124. The common axis A of the system formed by the optical light emitter and the optical detector, corresponding to the axis between the center of the optical light emitter and the center of the optical detector, is aligned with the horizontal direction X which corresponds to the direction of the rows 14 of pixels.

FIG. 1B shows a diffraction pattern observed when a light beam is emitted and received through an OLED layer 112.

The inventors have measured diffraction order angles for a light beam of a given wavelength, and determined a diffractive structure pitch, using the relation:

d×sin θ=m×λ

where d is the pitch of the diffractive structure, θ is the diffraction angle, m is the order number, and λ is the wavelength, for instance 940 nm.

The inventors have determined that the pitch of the diffractive structure was very close to the pitch between the subpixels of the OLED layer in the row and column directions. The pitch between the subpixels is for example measured as the distance between two adjacent subpixels in the row direction or in the column direction. Thus, the inventors determine that the diffraction is caused by the pixels, and particularly the subpixels, of the OLED layer, in other words, that the diffraction structure is formed by the subpixels of the OLED layer.

In addition, the inventors have noticed that the diffraction effect is more pronounced in the X direction and in the Y direction, corresponding respectively to the row orientation and the column orientation of the pixel arrangement, also corresponding to the two directions of the alternance of the red and blue subpixels.

Indeed, the diffraction structure in the OLED layer creates higher angles of emission along the X direction or the Y direction. As illustrated in FIG. 1C, higher angles mean that light can traverse from the emitter 122 to the detector 124 in fewer reflections in the cover glass 114 above the OLED layer 112, and thus, is less attenuated. For example, there is one reflection (bounce) in the illustrated case. If the angles are high enough, total internal reflection occurs and minimal attenuation occurs, inducing a crosstalk effect.

This diffraction effect increases the screen crosstalk contribution if the proximity sensor is orientated such that the emitter and detector common axis A is aligned in one of these two directions, as illustrated in FIG. 1A, which has a drawback of degrading the performances of the proximity sensor.

The inventors also determine that metallization of the pixels routing is important in creating the diffraction patterns. In particular, inventors determine that the pixels routing of metal in the row and column orientations are different, leading to different diffraction patterns in the X and Y directions.

The inventors create an assembly and a proximity sensor, making it possible to overcome all or part of the aforementioned drawbacks, for example to limit, or even suppress, the aforementioned crosstalk effect due to the diffraction effect.

Embodiments of assemblies and proximity sensors are described herein. These embodiments are non-limiting and various variants will appear to the person skilled in the art from the indications of the present description.

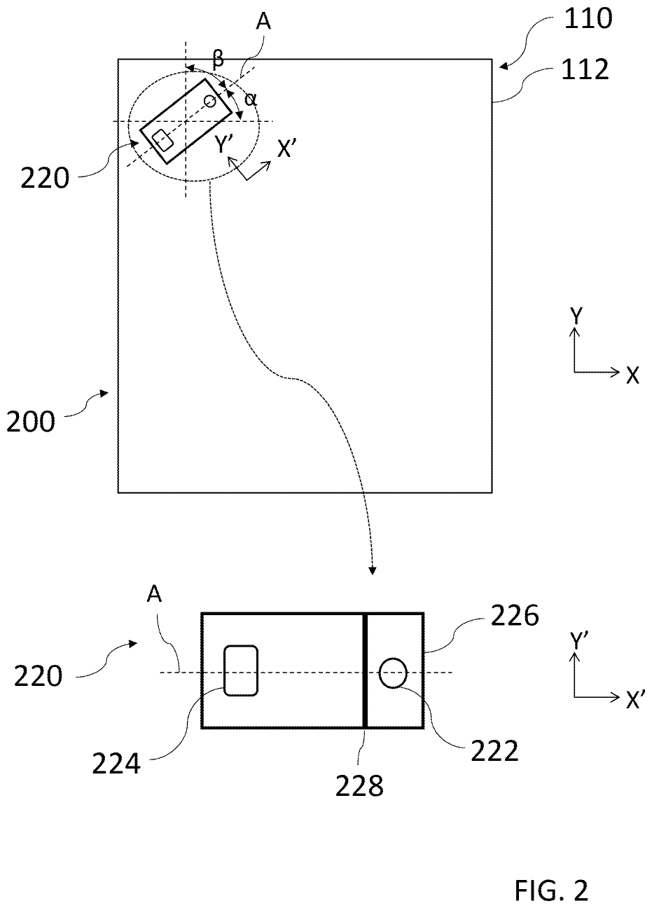

FIG. 2 illustrates an embodiment of an assembly 200 comprising a display screen 110 having a display layer 112, and a proximity sensor 220 under the display layer 112.

In some embodiments, the display layer 112 and the display screen 110 have a rectangular shape, the two opposite larger edges extending in a major axis Y (e.g., vertical direction), and the two opposite smaller edges extending in a minor axis X (e.g., horizontal direction).

The display screen may be an OLED display screen, and the display layer may be an OLED layer, as the one described in relation with FIG. 1A. The OLED display screen 110 may comprise a cover glass 114 on the OLED layer 112, as described for example in relation with FIG. 1C.

Referring to the OLED layer 112 of FIG. 1A, the OLED layer comprises pixels 10 arranged in rows 14 and columns 15. The rows are orientated in the horizontal direction X and the columns are orientated in the vertical direction Y.

The proximity sensor 220 comprises an optical light emitter 222 and an optical detector 224, both housed within an optical package 226.

The proximity sensor may be a time-of-flight (TOF) sensor type. The proximity sensor may be an intensity based sensor type.

The optical light emitter may be a VCSEL. It will be understood that any type of optical light emitter may be used, for instance a LED emitter.

The optical detector may be of any type of suitable optical detector. For example, the optical detector may include a single light sensitive pixel comprising a photodiode or a plurality of light sensitive pixels, each pixel comprising a photodiode. The proximity detector may include, or may be, a single photon avalanche detector (SPAD).

The optical package 226 and therefore the proximity sensor 220 have a rectangular shape, the two opposite larger edges extending in a major axis X′ corresponding to an horizontal direction in the referential of the proximity sensor, and the two opposite smaller edges extending in a minor axis Y′ corresponding to a vertical direction in the referential of the proximity sensor. The axis X′ and Y′ form the main plane of the proximity sensor 220.

The optical light emitter 222 and the optical detector 224 can be separated by a septum 228 internal to the optical package, the septum 228 being substantially parallel to the minor axis Y′ of the proximity sensor 220.

The common axis A passing through the center of the optical light emitter 222 and the center of the optical detector 224 is substantially aligned with the major axis X′ of the proximity sensor 220. In addition, the proximity sensor 220 is angularly offset with regard to the horizontal and vertical directions X, Y of the display screen 110, which correspond to the orientations of the rows and columns of pixels in the display layer 112. In other words, each of the axis X′, Y′ of the proximity sensor 220 is offset with regard to each of the horizontal and vertical directions X, Y of the display screen. More precisely, in the illustrated embodiment, the major axis X′ of the proximity sensor is offset with regard to the horizontal direction X (minor axis) of the display screen by a first acute angle α, and is offset with regard to the vertical direction Y (major axis) of the display screen by a second acute angle β, the second acute angle being complementary to the first acute angle.

The first acute angle α is in some embodiments higher than around 10° and in some embodiments lower than around 80°, for example comprised between around 10° and 45°, for instance equal to around 45°.

The result is that the common axis A passing through the center of the optical light emitter 222 and the center of the optical detector 224 is angularly offset with regard to each of the orientations of the rows and columns of pixels of the display screen, thus allowing the crosstalk effect, due to the diffraction effect, to be limited, and even suppressed.

In other words, when the optical light emitter 222 emits a light beam through one or more first pixels of the display screen 110, and the optical detector 224 receives through one or more second pixels of the display screen 110 the light beam emitted by the emitter and reflected on an object, none of the one or more second pixels is in the same row as any of the one or more first pixels and none of the one or more second pixels is in the same column as any of the one or more first pixels.

The assembly 200 of FIG. 2 can be obtained by providing a proximity sensor, such as the one of FIG. 1A, and rotating it before assembling it behind the display screen 110, in order to angularly offset said proximity sensor with regard to the horizontal and vertical directions X, Y of the display screen 110, which correspond to the orientations of the rows and columns of pixels in the display layer 112.

In an embodiment, the orientations of the rows and columns of the display layer are not in the horizontal and vertical directions of the display screen. In this another embodiment, the proximity sensor is orientated in order to be offset with regard to each of the orientations of the rows and columns of the display layer.

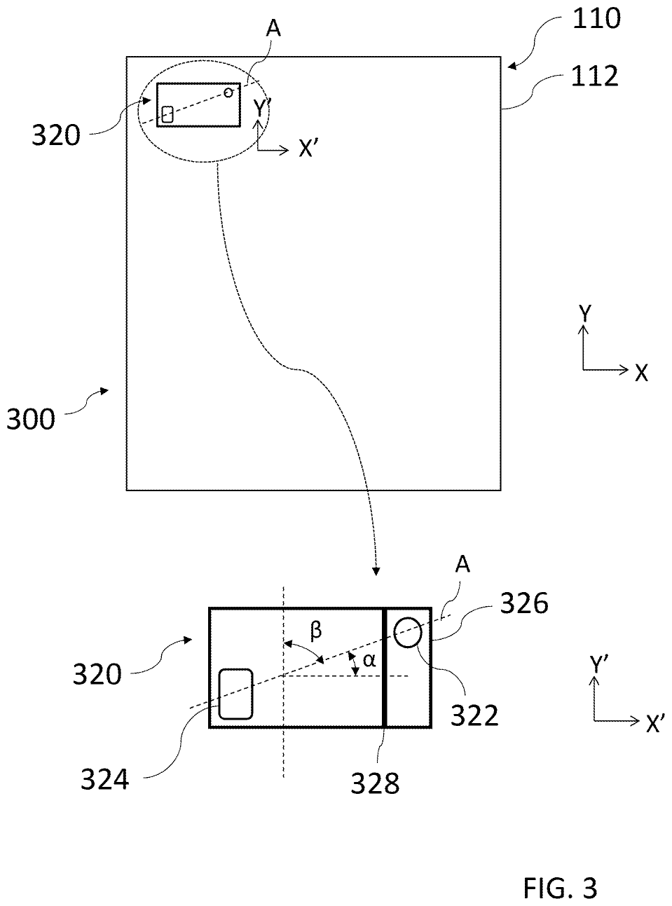

FIG. 3 illustrates an embodiment of an assembly 300 which differs from that of FIG. 2 in that the common axis A passing through the center of the optical light emitter 322 and the center of the optical detector 324 is offset with regard to the major axis X′ of the optical package 326 by a first acute angle α, and is offset with regard to the minor axis Y′ of the optical package by a second acute angle β, the second acute angle being complementary to the first acute angle. In addition, the major axis X′ of the proximity sensor 320 is substantially aligned with regard to the horizontal direction X (minor axis) of the display screen and the minor axis Y′ of the proximity sensor 320 is substantially aligned with the vertical direction Y (major axis) of the display screen.

The first acute angle α is in some embodiments higher than around 10°, and in some embodiments lower than around 80°, for example comprised between around 10° and 45°, for example equal to around 45°.

Since the horizontal direction X of the display screen 110 corresponds to the orientation of the rows of pixels in the display layer 112 and the vertical direction Y of the display screen 110 corresponds to the orientation of the columns of pixels in the display layer 112, the result is that the common axis A passing through the center of the optical light emitter 322 and the center of the optical detector 324 is angularly offset with regard to each of the row and column orientations of the display layer 112, thus allowing the crosstalk effect due to the diffraction effect, to be limited, an even suppressed.

In other words, when the optical light emitter 322 emits a light beam through one or more first pixels of the display screen 110, and the optical detector 324 receives through one or more second pixels of the display screen 110 the light beam emitted by the emitter and reflected on an object, none of the one or more second pixels is in the same row as any of the one or more first pixels and none of the one or more second pixels is in the same column as any of the one or more first pixels.

In comparison with the proximity sensor 220 of FIG. 2, the proximity sensor 320 of FIG. 3 can be obtained by offsetting the light emitter 322 and the optical detector 324 with regard to the major axis X′ of the optical package 326 before closing and/or encapsulating them to form the optical package.

Similarly to the proximity sensor 220 of FIG. 2, the optical light emitter 322 and the optical detector 324 can be separated by a septum 328 internal to the optical package 326, the septum 328 being substantially parallel to the minor axis Y′ of the proximity sensor 320.

The other features and embodiments described above for the assembly of FIG. 2 may also be applied to the assembly of FIG. 3.

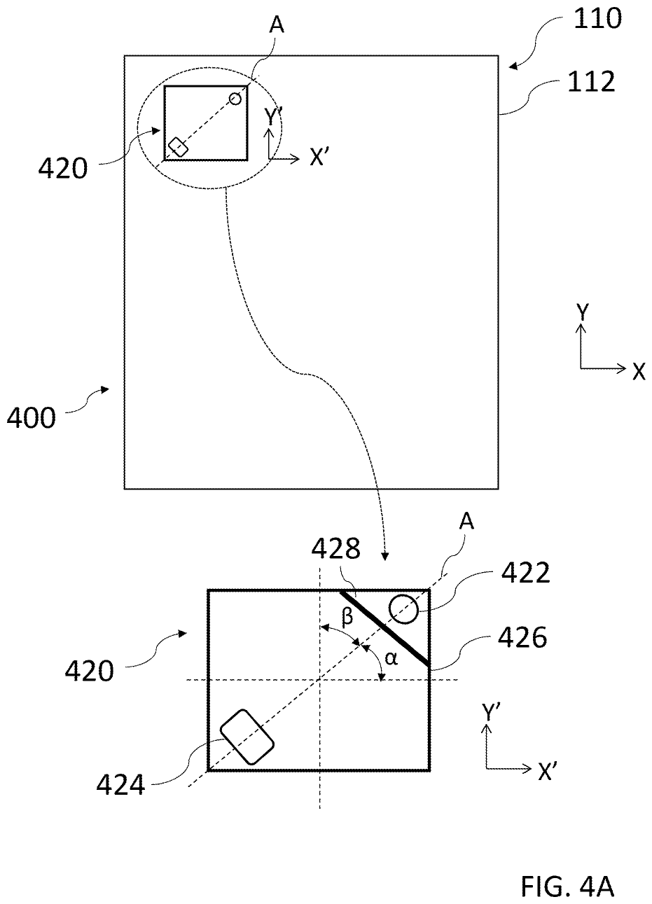

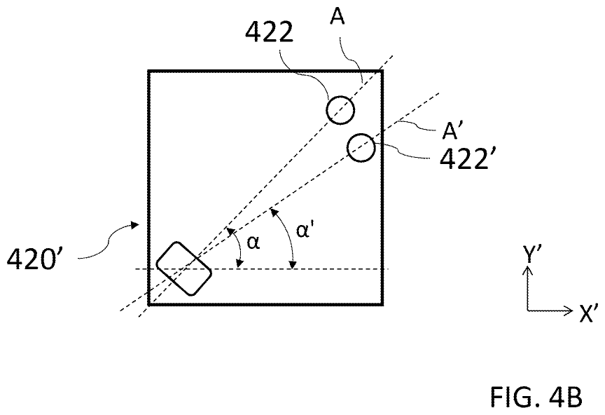

FIG. 4A illustrates an embodiment of an assembly 400 which differs from that of FIG. 3 in that the common axis A passing through the center of the optical light emitter 422 and the center of the optical detector 424 is substantially orientated in a diagonal of the optical package 426, which has a substantially square form. In addition, an optical detector 424 having an array of light sensitive pixels comprising rows and columns of light sensitive pixels is for instance orientated in order to align the rows of light sensitive pixels or the columns of light sensitive pixels substantially in the direction of the common axis A.

In the illustrated embodiment, the first acute angle α is equal to around 45°. In other embodiments, the first acute angle α can be comprised between around 10° and 80°, for example comprised between around 10° and 45°.

The proximity sensor 420 of FIG. 4A can be obtained by providing a Printed Circuit Board (PCB) or another substrate having substantially a square form, placing the light emitter 422 and the optical detector 424 on the PCB or substrate so that the common axis A passing through the center of the optical light emitter 422 and the center of the optical detector 424 is substantially orientated in a diagonal of said PCB or substrate, before closing with a cover and/or encapsulating the light emitter and the optical detector on the PCB or substrate to form an optical package 426.

In addition, an optical detector 424 having an array of light sensitive pixels comprising rows and columns of light sensitive pixels is for example rotated before forming the optical package, in order to align the rows of light sensitive pixels or the columns of light sensitive pixels in the direction of the common axis A.

The optical light emitter 422 and the optical detector 424 can be separated by a septum 428 internal to the optical package 426, the septum 428 being orientated substantially perpendicular to the common axis A (substantially perpendicular to the diagonal).

In an embodiment, the optical package 426 may have a rectangular form.

The other features and embodiments described above for the assembly of FIG. 2 or FIG. 3 may also be applied to the assembly of FIG. 4A.

The proximity sensor may comprise multiple optical light emitters. In this case, a common axis is an axis passing through the center of one of the multiple optical light emitters and the center of the optical detector, and each common axis is in some embodiments offset with regard to each of the row and column directions of the pixels in the matrix scheme. The same applies if there are multiple optical detectors, in which a common axis is an axis passing through the center of one of the multiple optical light emitters and the center of one of the optical detector. These cases can apply to any of the embodiments.

As an example, FIG. 4B illustrates a variant of the embodiment of FIG. 4A which differs mainly in that the proximity sensor 420′ comprises two optical light emitters 422, 422′. In addition, a first common axis A passing through the center of a first optical light emitter 422 and the center of the optical detector 424 is offset with regard to the major axis X′ by a first acute angle α and a second common axis A′ passing through the center of a second optical light emitter 422′ and the center of the optical detector 424 is offset with regard to the major axis X′ by a second acute angle α′. Each of the first and second acute angles can be comprised between around 10° and 80°, for example comprised between around 10° and 45°.

FIG. 5 schematically illustrates a reflection pattern of a light beam emitted from a proximity sensor 220 through an OLED screen 110 in an assembly 200 according to an embodiment. The assembly of FIG. 5 is referred as being the one of FIG. 2, but it could be any assembly according to an embodiment.

Since the common axis A passing through the center of the optical light emitter 222 and the center of the optical detector 224 is angularly offset with regard to each of the row and column orientations of the OLED layer 112, the proximity sensor 220 is less subjected to the diffraction effect induced by the pixel scheme in the OLED layer, which acts as a diffraction structure. Indeed, in the directions offset with regard to the row and column directions, the OLED layer 112 creates lower angles of emission. Therefore, there are at least three bounces of the light beam in the coverglass 114, further attenuating the diffraction effect in these directions (for example, attenuation of a 25 factor per bounce, given that three bounces are illustrated but it could be more than three, such as five or seven).

FIG. 6 represents measurements of the crosstalk effect (counts) for different angles, in the trigonometric direction, measured between the vertical direction Y of a display screen and the common axis A of a proximity sensor, the proximity sensor being under the display screen, with light beams emitted and received by the proximity sensor passing through the display screen.

The measurements are also shown in table 1 below, in which the corresponding acute angle β (with regard to the vertical direction Y of the display screen) and the corresponding acute angle α (with regard to the horizontal direction X of the display screen) are given in two other columns.

TABLE 1

| Measured | Corresponding | Corresponding | |
|---|---|---|---|
| angle | acute angle β | acute angle α | Counts |
| 0° | 0° | 90° | 1560 |
| 45° | 45° | 45° | 1216 |
| 90° | 90° | 0° | 1788 |
| 135° | 45° | 45° | 1260 |
| 180° | 0° | 90° | 1703 |
| 225° | 45° | 45° | 1198 |
| 270° | 90° | 0° | 1593 |
| 315° | 45° | 45° | 1170 |

The measurements show that the counts are higher when the common axis A is orientated in the vertical direction Y or in the horizontal direction X, but lower when the common axis A is orientated between the vertical direction Y and the horizontal direction X, thus proving the positive effect of offsetting the common axis A.

Various embodiments and variants have been described. Those skilled in the art will understand that certain features of these embodiments can be combined and other variants will readily occur to those skilled in the art. In particular, although some embodiments mentioned above refer to an OLED screen, it is to be appreciated that the assembly and the electronic device could comprise other display screens, the pixels of which induce the diffraction of a light beam passing through.

Finally, the practical implementation of the embodiments and variants described herein is within the capabilities of those skilled in the art based on the functional description provided hereinabove.

An assembly (200, 300, 400) for an electronic device, the assembly may be summarized as including a display screen (110) including a plurality of pixels (10) arranged in a matrix scheme comprising rows (14) orientated in a first direction (X) and columns (15) orientated in a second direction (Y); and a proximity sensor (220, 320, 420, 420′) including at least one optical light emitter (222, 322, 422, 422′), each adapted to emit a light beam through one or more first pixels of the display screen, and an optical detector (224, 324, 424) adapted to receive through one or more second pixels of the display screen the light beam emitted by the at least one optical light emitter and reflected on an object; wherein none of the one or more second pixels is in the same row as any of the one or more first pixels, and none of the one or more second pixels is in the same column as any of the one or more first pixels.

Each common axis (A, A′) passing through the center of one of the at least one optical light emitter (222, 322, 422, 422′) and the center of the optical detector (224, 324, 424) may be offset with regard to each of the first and second directions (X,Y) by an acute angle of at least 10° and at most 80°.

A first acute angle (a, a′) of the common axis (A, A′) with regard to the first direction (X) may be comprised between 10° and 45°.

A second acute angle ((3) of the common axis (A) with regard to the second direction (Y) may be comprised between 10° and 45°.

The display screen (110) being an OLED screen, each pixel of the OLED screen, may have for instance a pentile subpixel arrangement.

The at least one optical light emitter (222) and the optical detector (224) may be housed within an optical package (226), and each common axis (A) passing through the center of one of the at least one optical light emitter and the center of the optical detector may be substantially aligned with an edge of the optical package.

The at least one optical light emitter (322, 422, 422′) and the optical detector (324, 424) may be housed within an optical package (326, 426), and each common axis (A, A′) may pass through the center of one of the at least one optical light emitter and the center of the optical detector may be offset with regard to each of the edges of the optical package by an acute angle of at least 10° and at most 80°.

A proximity sensor (320, 420, 420′) may be summarized as including at least one optical light emitter (322, 422, 422′) each adapted to emit a light beam through a display screen, and an optical detector (324, 424) adapted to receive through the display screen the light beam emitted by the at least one optical light emitter and reflected on an object, wherein the at least one optical light emitter and the optical detector are housed within an optical package (326, 426), and each common axis (A, A′) passing through the center of one of the at least one optical light emitter and the center of the optical detector is offset with regard to each of the edges of the optical package by an acute angle of at least 10° and at most 80°.

The acute angle of each common axis (A, A′) with regard to each edge of the optical package may be comprised between 10° and 45°.

The optical package (426) may be substantially rectangular or square, and at least a common axis (A) may be substantially orientated substantially in a diagonal of the optical package.

The optical detector (424) may include an array of light sensitive pixels having rows and columns of light sensitive pixels, said optical detector being orientated in order to align said rows of light sensitive pixels or said columns of light sensitive pixels substantially in the direction of the common axis (A).

The proximity sensor (420′) may include at least two optical light emitters (422, 422′).

An electronic device may be summarized as including the assembly or the proximity sensor.

A method for forming an assembly (200, 300, 400) may be summarized as including a display screen (110) having a plurality of pixels (10) arranged in a matrix scheme comprising rows (14) orientated in a first direction (X) and columns (15) orientated in a second direction (Y), and a proximity sensor (220, 320, 420, 420′); the method including: placing a proximity sensor having at least one optical light emitter (222, 322, 422, 422′) and an optical detector (224, 324, 424) under the display screen, such that each of the at least optical light emitter is adapted to emit a light beam through one or more first pixels of the display screen, the optical detector (224, 324, 424) is adapted to receive through one or more second pixels of the display screen the light beam emitted by the at least one emitter and reflected on an object, none of the one or more second pixels being in the same row as any of the one or more first pixels, and none of the one or more second pixels being in the same column as any of the one or more first pixels.

The method may include providing a proximity sensor (220) having at least one optical light emitter (222) and an optical detector (224) both housed within an optical package (226), each common axis (A) passing through the center of one of the at least one optical light emitter and the center of the optical detector being substantially aligned with an edge of the optical package; positioning the proximity sensor (220) under the display screen (110); rotating the proximity sensor (220) in order to offset the edge of the optical package with regard to each of the first and second directions (X,Y) by an acute angle of at least 10° and at most 80°; and assembling the proximity sensor (220) to the display screen (110).

The method may include providing a proximity sensor (320, 420, 420′) having at least one optical light emitter (322, 422, 422′) and an optical detector (324, 424) both housed within an optical package (326, 426), each common axis (A, A′) passing through the center of one of the at least one optical light emitter and the center of the optical detector being offset with regard to each of the edges of the optical package by an acute angle of at least 10° and at most 80°; and assembling the proximity sensor (320, 420, 420′) under the display screen (110) so that each of the edges of the optical package may be substantially aligned with the first direction (X) or the second direction (Y).

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An assembly for an electronic device, the assembly comprising:
a display screen including a plurality of pixels arranged in a matrix scheme having rows orientated in a first direction and columns orientated in a second direction; and
a proximity sensor including at least one optical light emitter each adapted to emit a light beam through one or more first pixels of the display screen, and an optical detector adapted to receive through one or more second pixels of the display screen the light beam emitted by the at least one optical light emitter and reflected on an object,
wherein none of the one or more second pixels is in a same row as any one of the one or more first pixels, and none of the one or more second pixels is in a same column as any one of the one or more first pixels.

2. The assembly according to claim 1, wherein each common axis passing through a center of one of the at least one optical light emitter and a center of the optical detector is offset with regard to each of the first and second directions by an acute angle of at least 10° and at most 80°.

3. The assembly according to claim 2, wherein a first acute angle of the common axis with regard to the first direction is in a range between 10° and 45°.

4. The assembly according to claim 2, wherein a second acute angle of the common axis with regard to the second direction is in a range between 10° and 45°.

5. The assembly according to claim 1, wherein the display screen is an OLED screen, and each pixel of the OLED screen has a pentile subpixel arrangement.

6. The assembly according to claim 1, wherein the at least one optical light emitter and the optical detector are housed within an optical package, and each common axis passing through a center of one of the at least one optical light emitter and a center of the optical detector is substantially aligned with an edge of the optical package.

7. The assembly according to claim 1, wherein the at least one optical light emitter and the optical detector are housed within an optical package, and each common axis passing through a center of one of the at least one optical light emitter and a center of the optical detector is offset with regard to each of edges of the optical package by an acute angle of at least 10° and at most 80°.

8. The assembly according to claim 7, wherein the optical package is substantially rectangular or square, and at least one common axis is orientated substantially in a diagonal of the optical package.

9. The assembly according to claim 8, wherein the optical detector comprises an array of light sensitive pixels having rows and columns of light sensitive pixels, the rows of light sensitive pixels or the columns of light sensitive pixels substantially aligned with a direction of the at least one common axis.

10. The assembly according to claim 1, wherein the at least one optical light emitter includes at least two optical light emitters.

11. An electronic device comprising the assembly of claim 1.

12. A proximity sensor comprising at least one optical light emitter each adapted to emit a light beam through a display screen, and an optical detector adapted to receive through the display screen the light beam emitted by the at least one optical light emitter and reflected on an object,
wherein:
the at least one optical light emitter and the optical detector are housed within an optical package having four edges, and
each common axis passing through a center of one of the at least one optical light emitter and a center of the optical detector is offset with regard to each of the edges of the optical package by an acute angle of at least 10° and at most 80°.

13. The proximity sensor of claim 12, wherein the acute angle of each common axis with regard to each edge of the optical package is in a range between 10° and 45°.

14. The proximity sensor according to claim 12, wherein the optical package is substantially rectangular or square, and at least one common axis is orientated substantially in a diagonal of the optical package.

15. The proximity sensor according to claim 14, wherein the optical detector comprises an array of light sensitive pixels having rows and columns of light sensitive pixels, the rows of light sensitive pixels or the columns of light sensitive pixels aligned substantially in a direction of the at least one common axis.

16. The proximity sensor according to claim 12, wherein the at least one optical light emitter comprises at least two optical light emitters.

17. An electronic device comprising the proximity sensor of claim 12.

18. A method for forming an assembly including a display screen having a plurality of pixels arranged in a matrix scheme having rows orientated in a first direction and columns orientated in a second direction, the method comprising:
placing a proximity sensor having at least one optical light emitter and an optical detector under the display screen in a manner wherein:
each of the at least optical light emitter is adapted to emit a light beam through one or more first pixels of the display screen,
the optical detector is adapted to receive through one or more second pixels of the display screen the light beam emitted by the at least one emitter and reflected on an object, and
none of the one or more second pixels is in a same row as any one of the one or more first pixels, and none of the one or more second pixels is in a same column as any one of the one or more first pixels.

19. The method of claim 18, wherein the placing the proximity sensor includes:
providing the proximity sensor having the at least one optical light emitter and the optical detector both housed within an optical package, each common axis passing through a center of one of the at least one optical light emitter and a center of the optical detector being substantially aligned with an edge of the optical package;
positioning the proximity sensor under the display screen;
rotating the proximity sensor to offset an edge of the optical package with regard to each of the first and second directions by an acute angle of at least 10° and at most 80°; and
assembling the proximity sensor to the display screen.

20. The method of claim 18, wherein the placing the proximity sensor includes:
providing the proximity sensor having the at least one optical light emitter and the optical detector both housed within an optical package, each common axis passing through a center of one of the at least one optical light emitter and a center of the optical detector being offset with regard to each of edges of the optical package by an acute angle of at least 10° and at most 80°; and
assembling the proximity sensor under the display screen so that each of the edges of the optical package is substantially aligned with one of the first direction or the second direction.
